(19) United States
(12) Patent Application Publication
(10) Pub. No.: US 2021/0258520 A1
(43) Pub. Date: Aug. 19, 2021

(54) IMAGING DEVICE

(71) Applicant: Panasonic Intellectual Property Management Co., Ltd., Osaka (JP)

(72) Inventor: TSUTOMU KOBAYASHI, Osaka (JP)

(21) Appl. No.: 17/120,444

(22) Filed: Dec. 14, 2020

(30) Foreign Application Priority Data
Feb. 18, 2020 (JP) 2020-025655
Nov. 18, 2020 (JP) 2020-191591

(51) Int. Cl. H04N 5/369; H01L 27/30; H04N 5/351

(52) U.S. Cl. CPC H04N 5/3698; H04N 5/351; H01L 27/307

(57) ABSTRACT

An imaging device includes: a pixel electrode; a counter electrode; a photoelectric conversion layer that is located between the pixel electrode and the counter electrode and that generates signal charge; a charge accumulation portion that is connected to the pixel electrode to accumulate the signal charge; and a voltage supply circuit that alternately supplies a first voltage and a second voltage different from the first voltage to the counter electrode. The voltage supply circuit supplies a third voltage to the counter electrode in a period between a first period in which the first voltage is supplied and a second period that is subsequent to the first period and in which the second voltage is supplied. The second voltage is a voltage between the first voltage and the third voltage.

### BACKGROUND

### 1. Technical Field

The present disclosure relates to imaging devices.

### 2. Description of the Related Art

Heretofore, adjustment of luminance values of images output from an imaging device have been performed. The luminance values are adjusted, for example, according to the brightness or the like of a subject. The luminance value adjustment can be realized, for example, by adjusting the amount of light that is incident on pixels. The amount of incident light can be adjusted by, for example, adjustment of the diaphragm of a lens, exposure-time adjustment using a shutter, or light reduction using a neutral density (ND) filter. The luminance value adjustment can also be realized by adjusting the sensitivity of the pixels. When the sensitivity of the pixels is adjusted, the amount of positive or negative charge read from the pixels is adjusted. As a result of the adjustment of the amount of charge, the luminance values of an output image are adjusted.

Japanese Unexamined Patent Application Publication No. 2007-104114 discloses an imaging device that adjusts the sensitivity by controlling the length of time of applying a voltage to a photoelectric conversion layer included in each pixel. Japanese Unexamined Patent Application Publication No. 2017-135704 and Japanese Unexamined Patent Application Publication No. 2017-005051 each disclose an imaging device that adjusts the sensitivity by controlling the magnitude of a voltage applied to a photoelectric conversion layer included in each pixel.

### SUMMARY

One non-limiting and exemplary embodiment provides an imaging device that allows sensitivity adjustment while ensuring a frame rate.

In one general aspect, the techniques disclosed here feature an imaging device comprising: a first electrode; a second electrode; a photoelectric conversion layer that is located between the first electrode and the second electrode to generate signal charge; a charge accumulation portion that is connected to the first electrode to accumulate the signal charge; and a voltage supply circuit that alternately supplies a first voltage and a second voltage different from the first voltage to the second electrode. The voltage supply circuit supplies a third voltage to the second electrode in a period between a first period in which the first voltage is supplied and a second period that is subsequent to the first period and in which the second voltage is supplied; and the second voltage is a voltage between the first voltage and the third voltage.

According to the present disclosure, it is possible to provide an imaging device that allows sensitivity adjustment while ensuring a frame rate.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a schematic diagram illustrating an exemplary circuit configuration of an imaging device according to a first embodiment;

FIG. 2 is a schematic sectional view illustrating a device structure of each pixel in an imaging device according to the first embodiment;

FIG. 3A is a timing chart in an example;

FIG. 3B is a graph illustrating a relationship between a voltage at a counter electrode and pixel signal reading in the example;

FIG. 4 is a graph illustrating a relationship between the voltage at the counter electrode and the pixel signal reading in another example;

FIG. 5 is a schematic diagram of an RC series circuit;

FIG. 6A is a graph illustrating dependency of a response time of the RC series circuit on a resistance;

FIG. 6B is a graph illustrating dependency of the response time of the RC series circuit on a capacitance;

FIG. 6C is a graph illustrating dependency of the response time of the RC series circuit on a power supply;

FIG. 7 is a graph illustrating a relationship between the voltage at the counter electrode and the pixel signal reading in operation example 1 of the imaging device according to the first embodiment;

FIG. 8 is a graph illustrating a relationship between the voltage at the counter electrode and the pixel signal reading in operation example 2 of the imaging device according to the first embodiment;

FIG. 9 includes graphs each illustrating a voltage supplied by a voltage supply circuit in another operation example of the imaging device according to the first embodiment;

FIG. 10 includes graphs each illustrating a voltage supplied by the voltage supply circuit in yet another operation example of the imaging device according to the first embodiment; and

FIG. 11 is a block diagram illustrating one example of the configuration of a camera system according to a second embodiment.

### DETAILED DESCRIPTION

### Findings That Led to Present Disclosure

When a voltage applied to a photoelectric conversion layer included in a pixel in an imaging device is adjusted for sensitivity adjustment by using a counter electrode, the time constant of a circuit which is due to a high resistance and a large capacitance of the counter electrode to which the voltage is applied is large, thus delaying a response time from when the counter electrode reaches a predetermined voltage for sensitivity adjustment. As a result, the delay of the response time makes it difficult to ensure a frame rate. Alternatively, the voltage at the counter electrode does not reach a voltage needed for intended sensitivity adjustment, and thus the intended sensitivity adjustment cannot be performed. Thus, the present inventors have found that the response time delay due to the large time constant of the circuit when a voltage for sensitivity adjustment is applied to the pixels causes a problem that the frame rate cannot be ensured and a problem that the sensitivity adjustment cannot be performed.

Accordingly, the present disclosure provides an imaging device that allows sensitivity adjustment while ensuring the frame rate by reducing the response time.

An overview of one aspect of the present disclosure is as follows.

An imaging device according to one aspect of the present disclosure includes: a first electrode; a second electrode; a photoelectric conversion layer that is located between the first electrode and the second electrode to generate signal charge; a charge accumulation portion that is connected to the first electrode to accumulate the signal charge; and a voltage supply circuit that alternately supplies a first voltage and a second voltage different from the first voltage to the second electrode. The voltage supply circuit supplies a third voltage to the second electrode in a period between a first period in which the first voltage is supplied and a second period that is subsequent to the first period and in which the second voltage is supplied; and the second voltage is a voltage between the first voltage and the third voltage.

With this arrangement, the voltage supply circuit alternately supplies the first voltage and the second voltage to the second electrode to change the voltage applied to the second electrode, thereby adjusting the sensitivity when signal charge is accumulated in the charge accumulation portion connected to the first electrode. For example, the sensitivity can be adjusted based on the ratio of the length of a period in which the voltage at the second electrode is the first voltage to the length of a period in which the voltage at the second electrode is the second voltage. In addition, the voltage supply circuit supplies a third voltage in a period between the first period in which the first voltage is supplied and the second period in which the second voltage is supplied. The second voltage is a voltage between the first voltage and the third voltage, and thus, when the voltage that is supplied changes from the first voltage to the third voltage, the voltage that is supplied changes more greatly than in a case in which the voltage that is supplied changes from the first voltage to the second voltage. Thus, a change in the voltage at the second electrode for sensitivity adjustment is accelerated to reduce the response time, so that the voltage at the second electrode reaches a voltage needed for intended sensitivity adjustment in a shorter period of time than in a case in which the voltage supply circuit does not supply the third voltage. Hence, it is possible to realize an imaging device that allows sensitivity adjustment while ensuring the frame rate.

Also, a period in which the voltage supply circuit supplies the third voltage and a period in which the voltage supply circuit supplies the second voltage are provided. That is, since the voltage supply circuit supplies the third voltage whose voltage value changes greatly in only a certain period, so that the reliability of a transistor related to the circuit for supplying the voltage is more likely to be maintained. Thus, it is possible to suppress changes in the performance of transistors used for realizing the imaging device.

Also, for example, the first period may be longer than the second period.

With this arrangement, since the second period is shorter than the first period, the voltage supply circuit supplies the third voltage in a period between the first period and the second period to thereby make it possible to accelerate a change in the voltage at the second electrode, even when it is difficult to make the voltage reach a voltage needed for intended sensitivity adjustment.

In addition, for example, the voltage supply circuit may supply a fourth voltage to the second electrode in a period between the second period and the first period that is subsequent to the second period, and the first voltage may be a voltage between the second voltage and the fourth voltage.

With this arrangement, the voltage supply circuit supplies the fourth voltage in a period between the second period in which the second voltage is supplied and the first period in which the first voltage is supplied. The first voltage is a voltage between the second voltage and the fourth voltage, and thus, when the voltage that is supplied changes from the second voltage to the fourth voltage, the voltage that is supplied changes more greatly than in a case in which the voltage that is supplied changes from the second voltage to the first voltage. Thus, a change in the voltage at the second electrode for sensitivity adjustment is accelerated to reduce the response time, so that the voltage at the second electrode reaches a voltage needed for intended sensitivity adjustment in a shorter period of time than in a case in which the voltage supply circuit does not supply the fourth voltage. Hence, it is possible to realize an imaging device that allows voltage adjustment while ensuring the frame rate.

Also, a period in which the voltage supply circuit supplies the fourth voltage and a period in which the voltage supply circuit supplies the first voltage are provided. That is, since the voltage supply circuit supplies the fourth voltage whose voltage value changes greatly in only a certain period, so that the reliability of a transistor related to the circuit for supplying the voltage is more likely to be maintained. Thus, it is possible to suppress changes in the performance of transistors used for realizing the imaging device.

In addition, for example, the photoelectric conversion layer may have a first surface and a second surface that is opposite the first surface; and the first electrode may face the first surface of the photoelectric conversion layer, and the second electrode may face the second surface of the photoelectric conversion layer.

With this arrangement, the sensitivity can be adjusted using the second electrode facing the second surface that is opposite the first surface of the photoelectric conversion layer in which the first electrode is located.

In addition, for example, the photoelectric conversion layer may have a first surface and a second surface that is opposite the first surface; and the first electrode and the second electrode may face the first surface of the photoelectric conversion layer.

With this arrangement, the sensitivity can be adjusted using the first electrode and the second electrode that face the same surface of the photoelectric conversion layer.

Herein, the term “high sensitivity exposure period” and the term “low sensitivity exposure period” are used. The “high sensitivity exposure period” refers to a period in which higher sensitivity is obtained than in the “low sensitivity exposure period”. The “low sensitivity exposure period” refers to a period in which lower sensitivity is obtained than in the “high sensitivity exposure period”. The “low sensitivity” as used herein is a concept including a state in which the sensitivity is zero. Thus, the “low sensitivity exposure period” is a concept including a period in which the sensitivity is zero. Herein, ordinals “first, second, third, . . . ” may be used. When one element is denoted by any of the ordinals, it is not essential that the same type of element with a smaller ordinal exist.

It should be noted that general or specific embodiments may be implemented as a system, a method, an integrated circuit, a computer program, or a recording medium, such as a computer-readable compact disc read-only memory (CD-ROM), or may be implemented as any selective combination of a system, a method, an integrated circuit, a computer program, and a recording medium.

An imaging device according to the present embodiment will be described below with reference to the accompanying drawings.

However, an overly detailed description may be omitted herein. For example, a detailed description of already well-known things and a redundant description of substantially the same configuration may be omitted herein. This is to avoid the following description becoming overly redundant and to facilitate understanding of those skilled in the art. The accompanying drawings and the following description are provided so as to allow those skilled in the art to fully understand the present disclosure and are not intended to limit the subject matter recited in the claims.

In the accompanying drawings, elements that represent substantially the same configurations, operations, and effects are denoted by the same reference numerals. Also, numerical values described below are exemplary for specifically describing the present disclosure and are not limited to the numerical values exemplified in the present disclosure. Additionally, connection relationships between constituent elements are exemplary for specifically describing the present disclosure, and connection relationships for realizing the features in the present disclosure are not limited thereto.

Herein, the terms “parallel”, “vertical”, and so on representing inter-element relationships, terms representing element shapes, the terms “same”, “uniform”, and so on, and the ranges of numerical values are not only expressions representing exact meanings but also expressions representing substantially equivalent terms and ranges, for example, expressions meaning that the terms include, for example, differences of about several percent.

Herein, the terms “above” and “below” do not refer to an upper direction (vertically upper side) and a lower direction (vertically lower side) in absolute spatial recognition and are used as terms defined by relative positional relationships based on the order of stacked layers in a multilayered configuration. The terms “above” and “below” apply to not only cases in which a constituent element exists between two constituent elements arranged with a gap therebetween but also cases in which two constituent elements are arranged in close contact with each other. Also, the term “plan view” as used herein refers to a case in which an imaging device is viewed along a direction orthogonal to a major surface of a substrate of the imaging device.

### First Embodiment

First, a description will be given of an imaging device according to a first embodiment.

### [Circuit Configuration of Imaging Device]

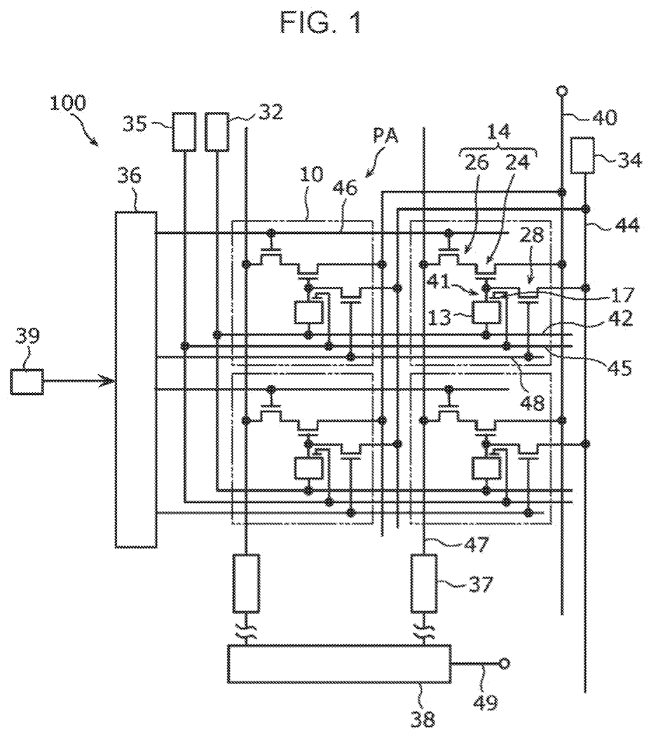

FIG. 1 is a schematic diagram illustrating an exemplary circuit configuration of an imaging device according to the first embodiment. An imaging device 100 illustrated in FIG. 1 has a pixel array PA including pixels 10 that are two-dimensionally arrayed. FIG. 1 schematically illustrates an example in which the pixels 10 are arranged in a matrix having two rows and two columns. The number of pixels 10 and the arrangement thereof in the imaging device 100 are not limited to the example illustrated in FIG. 1.

Each pixel 10 has a photoelectric converting portion 13, a signal detection circuit 14, and a shield electrode 17. As will be described later with reference to the accompanying drawings, each photoelectric converting portion 13 has a photoelectric conversion layer 15 sandwiched between two electrodes that oppose each other and generates signal charge in response to incident light. The photoelectric converting portion 13 does not necessarily have to be an independent element for each pixel 10, and for example, part of the photoelectric converting portion 13 may be provided across two or more pixels 10. The signal detection circuit 14 is a circuit that detects the signal charge generated by the photoelectric converting portion 13. In this example, the signal detection circuit 14 includes a signal detection transistor 24 and an address transistor 26. The signal detection transistor 24 and the address transistor 26 are, for example, field-effect transistors (FETs). In this case, the signal detection transistor 24 and the address transistor 26 are described as being n-channel metal-oxide-semiconductor field-effect transistors (MOSFETs) by way of example. Transistors, such as the signal detection transistor 24, the address transistor 26, and a reset transistor 28 described below, each have a control terminal, an input terminal, and an output terminal. The control terminal is, for example, a gate. The input terminal is one of a drain and a source and is, for example, a drain. The output terminal is the other of the drain and the source and is, for example, the source.

As schematically illustrated in FIG. 1, the control terminal of the signal detection transistor 24 has electrical connection with the photoelectric converting portion 13. The signal charge generated by the photoelectric converting portion 13 is accumulated in a charge accumulation portion 41. The charge accumulation portion 41 extends in a region including an area between the gate of the signal detection transistor 24 and the photoelectric converting portion 13. The signal charge is positive or negative charge and is, for example, holes or electrons. The charge accumulation portion 41 is a portion including the so-called floating diffusion. Details of the structure of the photoelectric converting portion 13 are described later.

The imaging device 100 includes a driver that drives the pixel array PA to acquire images at a plurality of timings. The driver includes a voltage supply circuit 32, a voltage supply circuit 35, a reset voltage source 34, a vertical scanning circuit 36, column signal processing circuits 37, a horizontal signal reading circuit 38, and a pixel drive signal generating circuit 39. The voltage supply circuit 32 and the voltage supply circuit 35 may be provided in a substrate in which constituent elements of the imaging device 100 are provided or may be provided outside the substrate in which the constituent elements of the imaging device 100 are provided. That is, the voltage supply circuit 32 and the voltage supply circuit 35 may be provided at a portion, such as a printed circuit board or a power supply board, other than the substrate in which the constituent elements of the imaging device 100 are provided.

The photoelectric converting portions 13 in the pixels 10 further have connections with corresponding sensitivity control lines 42. In the configuration illustrated in FIG. 1, the sensitivity control lines 42 are connected to the voltage supply circuit 32. As described below in detail, the voltage supply circuit 32 supplies a voltage that differs between in a high sensitivity exposure period and in a low sensitivity exposure period to a counter electrode 12. The voltage supply circuit 32 may also supply a voltage that differs one frame to another to the counter electrode 12. The voltage supply circuit 32 includes, for example, voltage sources for three or more different types of voltage and supplies the voltage of any of the voltage sources to the counter electrode 12 through switching of a transistor or the like. The voltage supply circuit 32 may also divide a voltage of one type of voltage source into three or more types of voltage and may supply one of the voltages to the counter electrode 12. This allows the voltage supply circuit 32 to supply a pulsed voltage having three or more values to the counter electrode 12.

The photoelectric converting portion 13 has a pixel electrode 11 and the photoelectric conversion layer 15, in addition to the counter electrode 12, as described below.

In the “high sensitivity exposure period” in the present embodiment, either positive or negative charge that is signal charge generated by photoelectric conversion is accumulated in the charge accumulation portion 41 at relatively high sensitivity. That is, in the “high sensitivity exposure period”, light is converted into an electrical signal at relatively high sensitivity. For example, increasing the potential difference between the pixel electrode 11 and the counter electrode 12 can enhance the sensitivity.

Also, in the “low sensitivity exposure period” in the present embodiment, either positive or negative charge that is signal charge generated by photoelectric conversion is accumulated in the charge accumulation portion 41 at relatively low sensitivity. That is, in the “low sensitivity exposure period”, light is converted into an electrical signal at relatively low sensitivity. The low sensitivity includes a sensitivity of zero. For example, reducing the potential difference between the pixel electrode 11 and the counter electrode 12 can reduce the sensitivity, and when the potential difference between the pixel electrode 11 and the counter electrode 12 is zero, the sensitivity also becomes zero.

In the configuration illustrated in FIG. 1, the shield electrode 17 has connection with the sensitivity control lines 45. The sensitivity control lines 45 are connected to the voltage supply circuit 35. The voltage supply circuit 35 supplies a shield voltage to the shield electrode 17. For example, the shield electrode 17 and the pixel electrodes 11 are electrically isolated from each other. The voltage supply circuit 35 may supply voltages that differ between in the high sensitivity exposure period and in the low sensitivity exposure period to the shield electrode 17. The voltage supply circuit 35 includes, for example, voltage sources for three or more different types of voltage and supplies the voltage of any of the voltage sources to the shield electrode 17 through switching of a transistor or the like. The voltage supply circuit 35 may also divide a voltage of one type of voltage source into three or more types of voltage and may supply one of the voltages to the shield electrode 17. This allows the voltage supply circuit 35 to supply a pulsed voltage having three or more values to the shield electrode 17.

The shield voltage at each shield electrode 17 can be used for transferring signal charge between the pixels 10, that is, can be used for suppressing crosstalk. For example, the crosstalk suppression can be realized by applying a shield voltage that is lower than a reset voltage Vr applied to the pixel electrodes 11 to the shield electrode 17. The reset voltage Vr is described later. The shield voltage applied to the shield electrode 17 may be a negative voltage.

The imaging device 100 does not necessarily have to have the sensitivity control lines 45 and the voltage supply circuit 35, and the shield electrode 17 may be connected to ground of the imaging device 100. Such an arrangement can also suppress crosstalk. The imaging device 100 does not necessarily have to have the shield electrode 17, the sensitivity control lines 45, and the voltage supply circuit 35.

The shield voltage at each shield electrode 17 can also be used to adjust the sensitivity of the photoelectric converting portion 13. For example, reducing the shield voltage to a voltage lower than the voltage applied to the pixel electrode 11 can reduce the sensitivity of the photoelectric converting portion 13. That is, the shield electrode 17 serves as an auxiliary electrode that adjusts the sensitivity of the photoelectric converting portion 13.

The voltage supply circuit 32 and the voltage supply circuit 35 are not limited to particular power supply circuits. Each of the voltage supply circuit 32 and the voltage supply circuit 35 may be a circuit that generates a predetermined voltage or may be a circuit that converts a voltage, supplied from another power supply, into a predetermined voltage.

Each pixel 10 has connection with a power-supply line 40 through which a power-supply voltage VDD is supplied. As illustrated in FIG. 1, an input terminal of each signal detection transistor 24 is connected to the power-supply line 40. Since the power-supply line 40 serves as a source-follower power supply, each signal detection transistor 24 amplifies the signal charge generated by the corresponding photoelectric converting portion 13 and outputs the amplified signal charge.

An input terminal of the address transistor 26 is connected to an output terminal of the signal detection transistor 24. An output terminal of the address transistor 26 is connected to one of vertical signal lines 47 arranged in respective columns of the pixel array PA. The control terminal of the address transistor 26 is connected to a corresponding address control line 46 to control the potential of the address control line 46 to thereby allow an output of the signal detection transistor 24 to be selectively read out to the corresponding vertical signal line 47.

In the illustrated example, the address control lines 46 are connected to the vertical scanning circuit 36. The vertical scanning circuit 36 is also referred to as a “row scanning circuit”. By applying a predetermined voltage to the address control lines 46, the vertical scanning circuit 36 selects the pixels 10, arranged in the rows, row by row. Then, reading of signals from the selected pixels 10 and resetting (described below) of the charge accumulation portion 41 are executed.

In addition, the pixel drive signal generating circuit 39 is connected to the vertical scanning circuit 36. In the illustrated example, the pixel drive signal generating circuit 39 generates a pixel drive signal for driving the pixels 10 arranged in the rows of the pixel array PA. The generated pixel drive signal is supplied to the pixels 10 in the row selected by the vertical scanning circuit 36.

The vertical signal lines 47 are main signal lines through which pixel signals from the pixel array PA are transmitted to a peripheral circuit. The column signal processing circuits 37 are connected to the vertical signal lines 47, respectively. The column signal processing circuits 37 are also referred to as “row signal accumulation circuits”. The column signal processing circuits 37 perform noise reduction signal processing, typified by correlated double sampling, and analog-to-digital conversion (AD conversion). As illustrated in FIG. 1, the column signal processing circuits 37 are provided so as to correspond to the respective columns of the pixels 10 in the pixel array PA. The horizontal signal reading circuit 38 is connected to the column signal processing circuits 37. The horizontal signal reading circuit 38 is also referred to as a “column scanning circuit”. The horizontal signal reading circuit 38 sequentially reads out signals from the column signal processing circuits 37 to a horizontal common signal line 49.

In the configuration illustrated in FIG. 1, each pixel 10 has a reset transistor 28. The reset transistor 28 can be, for example, a field-effect transistor, as in the signal detection transistor 24 and the address transistor 26. An example in which an n-channel MOSFET is used as the reset transistor 28 will be described below, unless otherwise particularly specified. As illustrated in FIG. 1, the reset transistor 28 is connected between a reset voltage line 44 through which the reset voltage Vr is supplied and the charge accumulation portion 41. The control terminal of the reset transistor 28 is connected to a corresponding reset control line 48 to control the potential of the reset control line 48 to thereby allow potentials of the pixel electrode 11 and the charge accumulation portion 41 to be reset to the reset voltage Vr. In this example, the reset control lines 48 are connected to the vertical scanning circuit 36. Accordingly, by applying a predetermined voltage to the reset control lines 48, the vertical scanning circuit 36 can reset the pixels 10, arranged in the rows, row by row.

In this example, the reset voltage line 44 through which the reset voltage Vr is supplied to the reset transistors 28 is connected to the reset voltage source 34. The reset voltage source 34 is also referred to as a “reset voltage supply circuit”. The reset voltage source 34 may have any configuration as long as it can supply the predetermined reset voltage Vr to the reset voltage line 44 during operation of the imaging device 100. The reset voltage source 34 is not limited to a power supply circuit, as in the above-described voltage supply circuit 32. Each of the voltage supply circuit 32, the voltage supply circuit 35, and the reset voltage source 34 may be a part of a single voltage supply circuit or may be an independent voltage supply circuit. At least one of the voltage supply circuit 32, the voltage supply circuit 35, and the reset voltage source 34 may be a part of the vertical scanning circuit 36. Alternatively, a sensitivity control voltage from the voltage supply circuit 32, a sensitivity control voltage from the voltage supply circuit 35 and/or the reset voltage Vr from the reset voltage source 34 may be supplied to each pixel 10 via the vertical scanning circuit 36.

The power-supply voltage VDD of the signal detection circuit 14 can also be used as the reset voltage Vr. In this case, a voltage supply circuit (not illustrated in FIG. 1) that supplies power-supply voltages to the pixels 10 and the reset voltage source 34 can be shared. Since the power-supply line 40 and the reset voltage line 44 can also be shared, wires in the pixel array PA can be simplified. However, making the reset voltage Vr different from the power-supply voltage VDD of the signal detection circuit 14 allows for more flexible control of the imaging device 100.

### [Device Structure of Pixels]

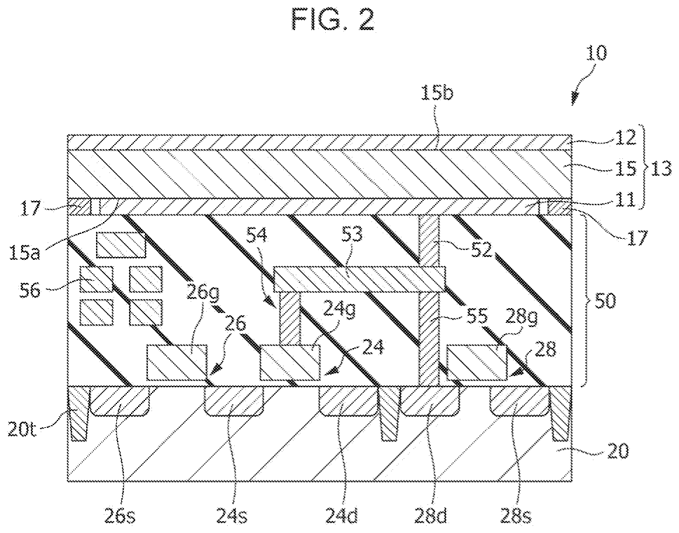

Next, a description will be given of a device structure of the pixels 10 in the imaging device 100. FIG. 2 is a schematic sectional diagram illustrating an exemplary device structure of each pixel 10. In the configuration illustrated in FIG. 2, the signal detection transistor 24, the address transistor 26, and the reset transistor 28, which are described above, are formed at a semiconductor substrate 20. The semiconductor substrate 20 is not limited to a substrate that is entirely made of semiconductor. The semiconductor substrate 20 may be an insulating substrate or the like having a semiconductor layer at a surface where a photosensitive region is formed. An example in which a P-type silicon (Si) substrate is used as the semiconductor substrate 20 will be described below.

The semiconductor substrate 20 has impurity regions 26s, 24s, 24d, 28d, and 28s and an element isolation region 20t for providing electrical isolation between the pixels 10. In this case, the impurity regions 26s, 24s, 24d, 28d, and 28s are n-type regions. The element isolation region 20t is also provided between the impurity region 24d and the impurity region 28d. The element isolation region 20t is formed, for example, by ion-implanting an acceptor under a predetermined implantation condition.

The impurity regions 26s, 24s, 24d, 28d, and 28s are, for example, impurity diffusion layers formed in the semiconductor substrate 20. As schematically illustrated in FIG. 2, the signal detection transistor 24 includes the impurity region 24s, the impurity region 24d, and a gate electrode 24g. The gate electrode 24g is formed using an electrically conductive material. The electrically conductive material is, for example, polysilicon that is given an electrical conductivity property by doping an impurity or may be a metallic material. The impurity region 24s serves as, for example, a source region of the signal detection transistor 24. The impurity region 24d serves as, for example, a drain region of the signal detection transistor 24. A channel region of the signal detection transistor 24 is formed between the impurity region 24s and the impurity region 24d.

Similarly, the address transistor 26 includes the impurity region 26s, the impurity region 24s, and a gate electrode 26g connected to the corresponding address control line 46 (see FIG. 1). The gate electrode 26g is formed using an electrically conductive material. The electrically conductive material is, for example, polysilicon that is given an electrical conductivity property by doping an impurity or may be a metallic material. In this example, the signal detection transistor 24 and the address transistor 26 share the impurity region 24s and are thus electrically connected to each other. The impurity region 24s serves as, for example, a drain region of the address transistor 26. The impurity region 26s serves as, for example, a source region of the address transistor 26. The impurity region 26s has connection with the corresponding vertical signal line 47 (see FIG. 1), which is not illustrated in FIG. 2. The impurity region 24s does not necessarily have to be shared by the signal detection transistor 24 and the address transistor 26. Specifically, the source region of the signal detection transistor 24 and the drain region of the address transistor 26 may be isolated from each other in the semiconductor substrate 20 and may be electrically connected via a wiring layer provided in an interlayer insulating layer 50.

The reset transistor 28 includes the impurity regions 28d and 28s and a gate electrode 28g connected to the corresponding reset control line 48 (see FIG. 1). The gate electrode 28g is formed, for example, using an electrically conductive material. The electrically conductive material is, for example, polysilicon that is given an electrical conductivity property by doping an impurity or may be a metallic material. The impurity region 28s serves as, for example, a source region of the reset transistor 28. The impurity region 28s has connection with the reset voltage line 44 (see FIG. 1), which is not illustrated in FIG. 2. The impurity region 28d serves as, for example, a drain region of the reset transistor 28.

The interlayer insulating layer 50 is formed above the semiconductor substrate 20 so as to cover the signal detection transistor 24, the address transistor 26, and the reset transistor 28. The interlayer insulating layer 50 is, for example, formed of insulating material, such as silicon dioxide. As illustrated in FIG. 2, wiring layers 56 are formed in the interlayer insulating layer 50. The wiring layers 56 are formed of, for example, metal, such as copper, and can include, for example, a signal line, such as the vertical signal line 47 described above, or a power-supply line. The number of insulating layers in the interlayer insulating layer 50 and the number of layers included in the wiring layers 56 arranged in the interlayer insulating layer 50 can be arbitrarily set and are not limited to the example illustrated in FIG. 2.

The photoelectric converting portion 13 and the shield electrode 17, which are described above, are arranged above the interlayer insulating layer 50. In other words, in the present embodiment, the pixels 10 that constitute the pixel array PA (see FIG. 1) are formed above the semiconductor substrate 20. The pixels 10 that are two-dimensionally arrayed above the semiconductor substrate 20 form a photosensitive region. The photosensitive region is also referred to as a “pixel region”. The distance between two adjacent pixels 10, that is, the pixel pitch, is, for example, about 2 μm.

The photoelectric converting portion 13 includes the pixel electrode 11, the counter electrode 12, and the photoelectric conversion layer 15 arranged therebetween. Herein, the pixel electrode 11 is one example of a first electrode, and the counter electrode 12 is one example of a second electrode. In this example, the counter electrode 12 and the photoelectric conversion layer 15 are formed across two or more pixels 10. The pixel electrodes 11 are provided for the respective pixels 10, and each pixel electrode 11 is spatially isolated from the pixel electrodes 11 in the adjacent pixels 10 and is thus electrically isolated from the pixel electrodes 11 in the other pixels 10.

In response to incident light, the photoelectric conversion layer 15 generates hole-electron pairs to generate signal charge. The photoelectric conversion layer 15 is located between the pixel electrode 11 and the counter electrode 12 in sectional view taken along a direction orthogonal to a major surface of the pixel electrode 11. Also, in plan view, the photoelectric conversion layer 15 overlaps the pixel electrode 11, the counter electrode 12, and the shield electrode 17. In plan view, the photoelectric conversion layer 15 is also located between the pixel electrode 11 and the shield electrode 17. The photoelectric conversion layer 15 is formed of, for example, an organic semiconductor material. The photoelectric conversion layer 15 has, for example, the shape of a film. The photoelectric conversion layer 15 has a first surface 15a, which is a major surface adjacent to the semiconductor substrate 20, and a second surface 15b, which is opposite the first surface 15a.

The counter electrode 12 is, for example, a transparent electrode formed of a transparent, electrically conductive material. The counter electrode 12 is arranged at a light incident side of the photoelectric conversion layer 15. Accordingly, light that passes through the counter electrode 12 is incident on the photoelectric conversion layer 15. The counter electrode 12 is located above the photoelectric conversion layer 15. That is, the counter electrode 12 is located adjacent to the second surface 15b of the photoelectric conversion layer 15. Although, in FIG. 2, the counter electrode 12 is in contact with the second surface 15b, it does not necessarily have to be in contact with the second surface 15b. Another layer, such as a block layer for blocking positive or negative charge, may be disposed between the counter electrode 12 and the photoelectric conversion layer 15. Light detected by the imaging device 100 is not limited to light in a visible-light wavelength range. For example, the imaging device 100 may detect infrared or ultraviolet. The visible-light wavelength range is, for example, larger than or equal to 380 nm and smaller than or equal to 780 nm. The “transparent” as used herein means transmitting at least part of light in a wavelength range to be detected and does not necessarily have to transmit light in the entire visible-light wavelength range. Herein, all electromagnetic waves including infrared and ultraviolet are referred to as “light”, for the sake of convenience. For example, a transparent conducting oxide (TCO), such as indium tin oxide (ITO), indium zinc oxide (IZO), aluminum-doped zinc oxide (AZO), fluorine-doped tin oxide (FTO), stannic oxide (SnO₂), titanium dioxide (TiO₂), or zinc peroxide (ZnO₂), can be used for the counter electrode 12.

As described above with reference to FIG. 1, the counter electrode 12 has connection with the corresponding sensitivity control line 42 connected to the voltage supply circuit 32. The counter electrode 12 may be formed across two or more pixels 10. With such an arrangement, a sensitivity control voltage having a desired magnitude can be applied from the voltage supply circuit 32 to two or more pixels 10 through the sensitivity control line 42 at a time. The counter electrode 12 can also be configured so that the sensitivity control voltage is applied for each row of the pixel array PA at a time. When the counter electrode 12 is formed across two or more pixels 10 in the manner described above, the capacitance and the resistance of the counter electrode 12 increase, and thus a response time relative to a change in the voltage is more likely to be delayed. However, in the present embodiment, the response time can be reduced, as described below. When a sensitivity control voltage having a desired magnitude can be applied from the voltage supply circuit 32, the counter electrode 12 may be separately provided for each pixel 10. Similarly, the photoelectric conversion layer 15 may be separately provided for each pixel 10.

Each pixel electrode 11 is an electrode for collecting signal charge generation by the photoelectric converting portion 13. At least one pixel electrode 11 is provided for each pixel 10. The pixel electrode 11 is arranged so as to oppose the counter electrode 12. The pixel electrode 11 is located below the photoelectric conversion layer 15. That is, the pixel electrode 11 is located adjacent to the first surface 15a of the photoelectric conversion layer 15. Although the pixel electrode 11 is in contact with the first surface 15a in FIG. 2, it does not necessarily have to be in contact with the first surface 15a, and another layer, such as a block layer for blocking positive or negative charge, may be disposed between the pixel electrode 11 and the photoelectric conversion layer 15.

Controlling the potential of the counter electrode 12 relative to the potential of the pixel electrode 11 allows the pixel electrode 11 to collect, as signal charge, either holes, which are positive charge, or electrons, which are negative charge, of hole-electron pairs generated in the photoelectric conversion layer 15 by photoelectric conversion. For example, when holes are used as the signal charge, making the potential of the counter electrode 12 higher than the potential of the pixel electrode 11 allows the pixel electrode 11 to selectively collect holes. Also, the amount of signal charge collected per unit time changes according to the potential difference between the pixel electrode 11 and the counter electrode 12. A case in which holes are used as the signal charge will be described below by way of example. Electrons can also be used the signal charge. In this case, the potential of the counter electrode 12 may be made lower than the potential of the pixel electrode 11.

The pixel electrode 11 is formed of metal, such as aluminum or copper, metal nitride, or polysilicon or the like given an electrical conductivity property by doping an impurity.

The pixel electrode 11 may be an electrode having a light-shielding property. For example, a sufficient light-shielding property can be realized by forming a tantalum nitride (TaN) electrode having a thickness of 100 nm as the pixel electrode 11. When the pixel electrode 11 is an electrode having a light-shielding property, it is possible to suppress incidence of light that passes through the photoelectric conversion layer 15 on the channel region or the impurity region of a transistor formed at the semiconductor substrate 20. In the illustrated example, the transistor is at least one of the signal detection transistor 24, the address transistor 26, and the reset transistor 28. The wiring layers 56 described above may be used to form a light-shielding film in the interlayer insulating layer 50. When the incidence of light on the channel region of the transistor formed at the semiconductor substrate 20 is suppressed by the electrode having a light-shielding property or the light-shielding film, for example, it is possible to suppress shifting or the like of transistor characteristics, such as variations in a threshold voltage of the transistor. Also, when incidence of light on the impurity region formed at the semiconductor substrate 20 is suppressed, it is possible to suppress noise mixing caused by unintended photoelectric conversion in the impurity region. The suppression or reduction of light incidence on the semiconductor substrate 20 contributes to enhancing the reliability of the imaging device 100.

As schematically illustrated in FIG. 2, the pixel electrode 11 is connected to the gate electrode 24g of the signal detection transistor 24 through a plug 52, a wire 53, and a contact plug 54. In other words, the gate of the signal detection transistor 24 has electrical connection with the pixel electrode 11. The plug 52 and the wire 53 can be formed of, for example, metal such as copper. The plug 52, the wire 53, and the contact plug 54 constitute at least a part of the charge accumulation portion 41 (see FIG. 1) between the signal detection transistor 24 and the photoelectric converting portion 13. The wire 53 can be a part of the wiring layer 56. The pixel electrode 11 is also connected to the impurity region 28d through the plug 52, the wire 53, and a contact plug 55. In the configuration illustrated in FIG. 2, at least a part of the gate electrode 24g of the signal detection transistor 24, the plug 52, the wire 53, and the contact plugs 54 and 55, the impurity region 28d, which is one of the source region and drain region of the reset transistor 28, serves as the charge accumulation portion 41 that accumulates signal charge collected by the pixel electrode 11.

When the pixel electrode 11 collects the signal charge, a voltage corresponding to the amount of the signal charge accumulated in the charge accumulation portion 41 is applied to the gate of the signal detection transistor 24. The signal detection transistor 24 amplifies the voltage. A signal voltage resulting from the amplification performed by the signal detection transistor 24 is selectively read out via the address transistor 26 as a pixel signal.

The shield electrode 17 is disposed so as to oppose the counter electrode 12. The shield electrode 17 is located below the photoelectric conversion layer 15. That is, the shield electrode 17 is located adjacent to the first surface 15a of the photoelectric conversion layer 15. Although, in FIG. 2, the shield electrode 17 is in contact with the first surface 15a, it does not necessarily have to be in contact with the first surface 15a. Another layer, such as a block layer for blocking positive or negative charge, may be disposed between the shield electrode 17 and the photoelectric conversion layer 15. Also, an insulating layer may be disposed between the shield electrode 17 and the photoelectric conversion layer 15.

The shield electrode 17 and the pixel electrode 11 are spaced from each other. In plan view, the shield electrode 17 may surround the pixel electrodes 11. More specifically, the shield electrode 17 may have through holes therein, and each through hole may accommodate one pixel electrode 11. The shield electrode 17 may be a single continuous electrode in the imaging device 100 or may be constituted by electrodes that are separated from each other.

The imaging device 100 described above can be manufactured using a general semiconductor manufacturing process. In particular, when a silicon substrate is used as the semiconductor substrate 20, the imaging device 100 can be manufactured using various types of silicon semiconductor process.

### [Operation of Imaging Device]

Next, a description will be given of the operation of the imaging device 100.

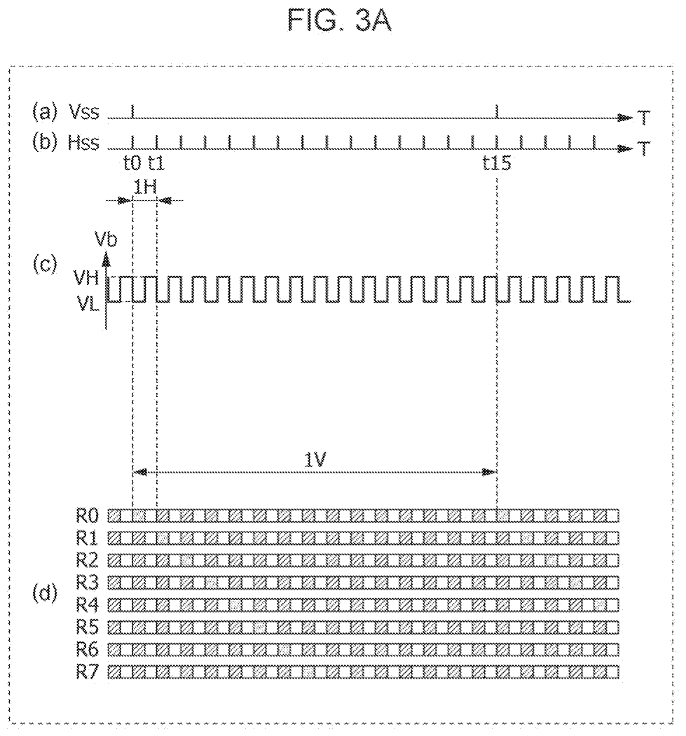

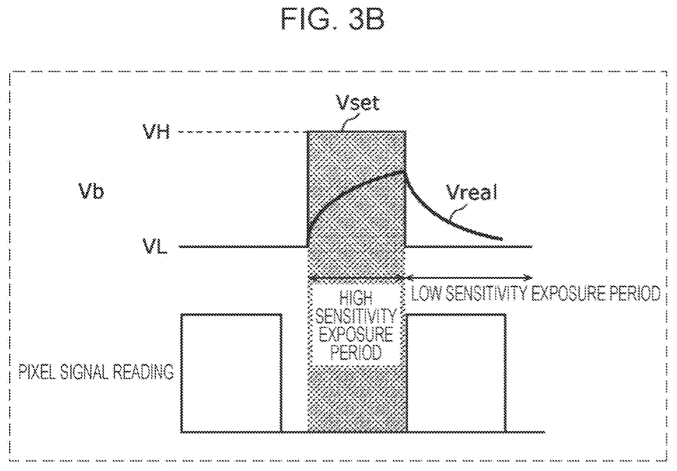

First, a case in which the voltage supply circuit 32 in the imaging device 100 supplies two different types of voltage to the counter electrode 12 will be described with reference to FIGS. 3A, 3B, 4 as an example of the operation of the imaging device 100. FIG. 3A is a timing chart of an example of the operation of the imaging device 100. Graph (a) in FIG. 3A illustrates timings of falling (or rising) of a vertical synchronization signal Vss. Graph (b) in FIG. 3A illustrates timings of falling (or rising) of a horizontal synchronization signal Hss. Graph (c) in FIG. 3A illustrates one example of changes over time in a voltage V applied from the voltage supply circuit 32 to the counter electrode 12 through the sensitivity control line 42. Graph (d) in FIG. 3A schematically illustrates a timing of resetting and timings of high sensitivity exposure and low sensitivity exposure in each row of the pixel array PA. For simplicity, a description in this case will be given of an example of operation when the total number of rows of the pixels included in the pixel array PA is eight rows, that is, R0^{th} to R7^{th} rows.

First, resetting of a charge accumulation region in each unit pixel cell 10 in the pixel array PA and reading of pixel signals after the resetting are executed in order to acquire an image. For example, as illustrated in FIG. 3A, resetting of the pixels belonging to the R0^{th} row is started based on the vertical synchronization signal Vss (time t0). Rectangles denoted by halftone dots in FIG. 3A schematically represent signal reading periods. Some of the reading periods can include reset periods for resetting the potentials of the charge accumulation regions in the unit pixel cells 10.

In a resetting operation of the pixels belonging to the R0^{th} row, the potential of the address control line 46 in the R0^{th} row is controlled to turn on the address transistors 26 whose gates are connected to the address control line 46. In addition, the potential of the reset control line 48 in the R0^{th} row is controlled to turn on the reset transistors 28 whose gates are connected to the reset control line 48. As a result, the charge accumulation portions 41 and the reset voltage line 44 are connected to each other, so that the reset voltage Vr is supplied to the charge accumulation regions. That is, the potentials of the gate electrodes 24g of the signal detection transistors 24 and the pixel electrodes 11 of the photoelectric converting portions 13 are reset to the reset voltage Vr. Thereafter, pixel signals after the resetting are read from the unit pixel cells 10 in the R0^{th} row through the vertical signal lines 47. The pixel signals obtained at this point in time are pixel signals corresponding to the magnitude of the reset voltage Vr. After the pixel signals are read, the reset transistors 28 and the address transistors 26 are turned off.

In this example, as schematically illustrated in FIG. 3A, the pixels belonging to each of the R0^{th} to R7^{th} rows is sequentially reset row by row in accordance with the horizontal synchronization signal Hss. That is, the pixel array PA is driven by a rolling shutter system. The pulse interval of the horizontal synchronization signal Hss, in other words, a period from when one row is selected until the next row is selected, may hereinafter be referred to as a “1H period”. In this example, for example, the period from time t0 to time t1 corresponds to the 1H period.

As illustrated in FIG. 3A, in a last half of the 1H period, a voltage VH supplied from the voltage supply circuit 32 is applied to the counter electrode 12. The voltage VH is a voltage during photography, that is, a voltage during charge accumulation, and is, for example, about 10 V (time t0 to time t15).

In FIG. 3A, white rectangles schematically represent the high sensitivity exposure periods in each row. Each high sensitivity exposure period is started when the voltage supply circuit 32 switches the voltage, applied to the counter electrode 12, to the voltage VH, which is higher than a voltage VL. Periods indicated by dotted rectangles and hatched rectangles in FIG. 3A schematically represent the low sensitivity exposure periods. Each low sensitivity exposure period is started when the voltage supply circuit 32 switches the voltage, applied to the counter electrode 12, to the voltage VL. The voltage VL is lower than the voltage VH and is, typically, a voltage at which the potential difference between the pixel electrode 11 and the counter electrode 12 reaches 0 V or less. The voltage VL may be, for example, approximately the same as the reset voltage for the charge accumulation portion.

In a state in which a bias voltage applied to the photoelectric conversion layer 15 is 0 V, almost all the charge generated in the photoelectric conversion layer 15 vanishes. The reason is assumed to be that almost all positive and negative charge generated by light illumination recombines quickly and vanishes. Meanwhile, the signal charge accumulated in the charge accumulation portion during high sensitivity exposure is held without being lost until the resetting operation of the pixel is performed. In a next 1H period, the voltage that the voltage supply circuit 32 applies to the counter electrode 12 is re-switched to the voltage VL to thereby start the low sensitivity exposure again. As described above, in each 1H period, the low sensitivity exposure period and the high sensitivity exposure period are repeated (time t0 to time t15). As a result of switching of the voltage applied to the counter electrode 12 between the voltage VL and the voltage VH, the high sensitivity exposure period and the low sensitivity exposure period are switched therebetween in each 1H period.

As described above, during the low sensitivity exposure period, the signal charge accumulated in the charge accumulation portion is maintained. As a result, even when the high sensitivity exposure period and the low sensitivity exposure period are repeated, the signal charges accumulated in the high sensitivity exposures are integrated. When a positive bias voltage is applied to the photoelectric conversion layer during the low sensitivity exposure, the signal charges are also accumulated during the low sensitivity exposure. In such a case, the signal charges accumulated during the low sensitivity exposures, in addition to the signal charges accumulated during the high sensitivity exposures, are also integrated. Also, the exposure time can also be varied by varying the ratio of the length of the high sensitivity exposure period to the length of the low sensitivity exposure period, that is, the duty ratio of the voltage applied to the counter electrode 12, in each 1H period. This makes it possible to adjust the sensitivity.

Next, the signal charges from the pixels belonging to each row in the pixel array PA are read based on the horizontal synchronization signal Hss. In this example, after time t15, the reading of the signal charges from the pixels belonging to the R0^{th} to R7^{th} rows is sequentially executed row by row. A period from when the pixels belonging to one row are selected until the pixels belonging to the row are selected again may hereinafter be referred to as a “1V period”. In this example, the period from time t0 to time t15 corresponds to the 1V period for the R0^{th} row. The 1V period is also a one-frame period for each row. Accordingly, with respective to each row, a plurality of high sensitivity exposure periods is repeated in one-frame period to thereby perform multiple exposure.

At time t15 after the 1V period in which the high sensitivity exposure period and the low sensitivity exposure period are repeated ends, the signal charges are read from the pixels belonging to the R0^{th} row. At this point in time, the address transistors 26 in the R0^{th} row are turned on. As a result, pixel signals corresponding to the amounts of charges accumulated in the charge accumulation portions in the plurality of high sensitivity exposure periods are output to the vertical signal lines 47. The reading of the pixel signals may be followed by pixel resetting by turning on the reset transistors 28. After the pixel signals are read, the address transistors 26 (and the reset transistors 28) are turned off. After the signal charges are read, a difference between the signals read at time t0 and the signals read at time t15 is determined. As a result, signals from which fixed noise is removed are obtained. Subsequently, a next 1V period is started for each row. The signals read from the rows are combined to acquire an image for one frame. Owing to the rolling shutter operation, the timings of the start and end of the exposure period and the timings of the signal reading and pixel resetting differ from one row to another. When viewed as an entire image, however, the high sensitivity exposure period and the low sensitivity exposure period are repeated to perform multiple exposure in one-frame period, so that captured-image data in the high sensitivity exposure period is obtained at a plurality of timings. The combination of the signal charges resulting from the multiple exposure is performed in the charge accumulation portion in each pixel cell.

FIG. 3B is a graph illustrating a relationship between the voltage at the counter electrode 12 and the pixel signal reading in this example. “Vb” in the upper stage in FIG. 3B is a graph illustrating changes in a voltage Vb at the counter electrode 12 over time. In “Vb” in FIG. 3B, a voltage Vset is a voltage that the voltage supply circuit 32 supplies to the counter electrode 12. In other words, the voltage Vset is a voltage at the counter electrode 12 which is needed for intended sensitivity adjustment. Also, in “Vb” in FIG. 3B, a voltage Vreal is a voltage applied to the counter electrode 12 in practice. That is, the voltage Vreal is an actual voltage at the counter electrode 12. The “pixel signal reading” in the lower stage in FIG. 3B is a graph illustrating the timing of the pixel signal reading. In the “pixel signal reading” in FIG. 3B, each rectangle represents a signal reading period in which the signal charge accumulated in the pixel 10 is read. The signal charge is read at any point in time in each rectangular period. Also, in FIG. 3B, the high sensitivity exposure period is denoted by a dot pattern.

In FIG. 3B, the high sensitivity exposure period is described as being a period in which a high-level voltage VH is applied to the counter electrode 12 to thereby provide relatively high sensitivity. The low sensitivity exposure period is a period in which a low-level voltage VL is applied to the counter electrode 12 to thereby provide relatively low sensitivity. Such sensitivity adjustment is performed, for example, when holes are used as the signal charge, and the reset voltage Vr has a value that is closer to the low-level voltage VL than to the high-level voltage VH. Also, the signal reading is performed in the low sensitivity exposure period. That is, after the pixel 10 is reset, the signal charge accumulated in the pixel 10 in the high sensitivity exposure period and the low sensitivity exposure period is read in the low sensitivity exposure period. The signal charge reading may also be sequentially performed row by row or every two or more rows in the low sensitivity exposure period. No signal charge may be virtually accumulated in the low sensitivity exposure period. That is, the sensitivity in the low sensitivity exposure period may be substantially zero. The signal charge accumulated in the pixel 10 may also be read in the high sensitivity exposure period.

The above description also applies to FIGS. 4, 7, and 8 described below.

It is assumed that, as in the voltage Vset illustrated in FIG. 3B, the voltage supply circuit 32 attempts to change the voltage Vb at the counter electrode 12 to two-value pulsed voltages, that is, the low-level voltage VL and the high-level voltage VH. That is, the voltage supply circuit 32 supplies the pulsed voltage Vset to the counter electrode 12. Even when the voltage supply circuit 32 supplies the pulsed voltage Vset in the manner described above, the voltage Vreal cannot change sharply in practice, owing to a delay caused by a resistance-capacitance (RC) time constant due to a resistance R and a capacitance C of the counter electrode 12 or a delay caused by an RC time constant due to a resistance R and a capacitance C of a wiring path from the voltage supply circuit 32 to the counter electrode 12. In FIG. 3B, the high sensitivity exposure period finishes before the voltage Vreal increases to a level that is sufficiently close to the voltage Vset, that is, the voltage VH. In this case, since the high sensitivity exposure period finishes when the sensitivity is not sufficiently increased, there is a possibility that a favorable image is not acquired owing to the insufficient sensitivity. Thus, in this example, the sensitivity cannot be adjusted to an intended sensitivity.

The problem due to the RC time constant can also occur in the low sensitivity exposure period in which the signal reading of the pixels 10 is performed. Specifically, in the low sensitivity exposure period, there is a possibility that the low sensitivity exposure period finishes before the voltage Vreal decreases to a level that is sufficiently close to the voltage VL. In this case, since the potential of the counter electrode 12 during resetting and reading that are performed in the low sensitivity exposure period is not stable, there is a possibility that a favorable image is not acquired.

Next, a description will be given of a case in which the high sensitivity exposure period is increased in order to overcome the problem in the sensitivity insufficiency described above with reference to FIG. 3B. FIG. 4 is a graph illustrating a relationship between the voltage at the counter electrode 12 and the pixel signal reading in another example. As illustrated in FIG. 4, since the high sensitivity exposure period is long, the voltage Vreal reaches the voltage Vset, that is, the voltage VH, so that the sensitivity is increased to an intended sensitivity. However, since the RC time constant due to the resistance R and the capacitance C of the counter electrode 12 is large, it takes time for the voltage Vreal to reach the voltage Vset. That is, the response time is delayed. In this example, although the sensitivity can be adjusted to an intended sensitivity, as described above, the high sensitivity exposure period increases, and thus the intervals of the pixel signal reading increase. Thus, the frame rate decreases, thereby making it difficult to ensure the frame rate.

Although a case in which the voltage supply circuit 32 adjusts the sensitivity of the photoelectric converting portion 13 by changing the voltage supplied to the counter electrode 12 has been described with reference to FIGS. 3B and 4, a similar problem occurs when the voltage supply circuit 35 adjusts the sensitivity of the photoelectric converting portion 13 by changing the voltage supplied to the shield electrode 17.

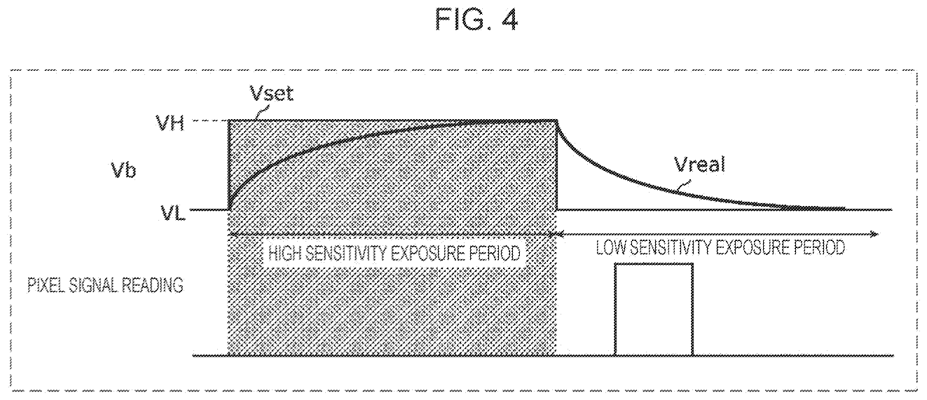

Now, the RC time constant that causes the sensitivity insufficiency and the frame rate reduction will be discussed. The circuit that applies the voltage to the counter electrode 12 or the shield electrode 17 can be thought as an RC series circuit including a resistance and a capacitance related to the counter electrode 12 or the shield electrode 17. FIG. 5 is a schematic diagram of the RC series circuit. The RC series circuit illustrated in FIG. 5 is constituted by a resistance R [Ω], a capacitance C [F], a direct-current (DC) power supply E [V], and a switch S. The charge accumulated in the capacitance C before the switch S is turned on is assumed to be zero. That is, charge q(0)=0 is given for time t=0. Since a transient phenomenon occurs when the switch S of the circuit is turned on, electrical current e that flows in the circuit changes over time, and then, when a certain amount of time passes, the electrical current e settles to a certain value. It is known that the response time of the resistance R can be determined according to equation (1) below:

$$e R ( t ) = E \cdot {e}^{- \frac{1}{CR} t} \qquad ( 1 )$$

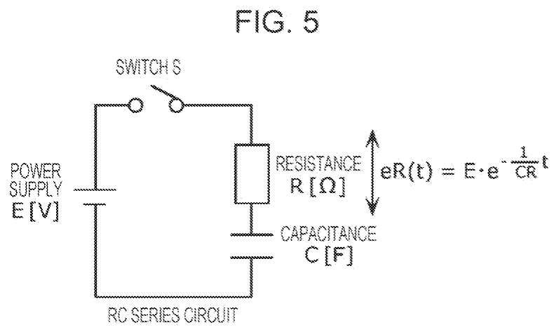

As indicated by this equation, the response time of the resistance R changes according to the resistance R, the capacitance C, and the DC power supply E. The response time of the resistance R in FIG. 5 will be described with reference to FIGS. 6A, 6B, and 6C. FIG. 6A is a graph illustrating dependency of the response time of the RC series circuit on the resistance R. FIG. 6B is a graph illustrating dependency of the response time of the RC series circuit on the capacitance C. FIG. 6C is a graph illustrating dependency of the response time of the RC series circuit on the DC power supply E. FIGS. 6A, 6B, and 6C are graphs obtained by plotting with respect to the response time of the resistance R. The vertical axis in each of FIGS. 6A, 6B, and 6C represents E-eR(t) [V], that is, the potential of a connection point of the resistance R and the capacitance C. The horizontal axis in each of FIGS. 6A, 6B, 6C represents an elapsed time from when the switch S is turned on. The potential difference between the connection point of the resistance R and the capacitance C and ground will hereinafter be referred to as a “potential of the resistance R”.

In FIGS. 6A, 6B, and 6C, the resistance R, the capacitance C, and the DC power supply E have default settings, that is, setting values that serve as references are R=200Ω, C=20 nF, and E=10 V. In FIG. 6A, the resistance R is changed from 200Ω to 40Ω in increments of 40Ω. In FIG. 6B, the capacitance C is changed from 20 nF to 4 nF in increments of 4 nF. In FIG. 6C, the power supply E is changed from 10 V to 18 V in increments of 2 V. In FIGS. 6A, 6B, and 6C, the response time that is taken for the potential of the resistance R to change from 0 V to 8 V is about 6 ns in the default settings.

For reducing the response time in the default settings to half by only changing the resistance R, it is necessary to reduce the resistance R to about 80Ω, as illustrated in FIG. 6A. Reducing the resistance R from 200Ω to 80Ω is not easy, and it is thus difficult to realize it. For reducing the response time in the default settings to half by only changing the capacitance C, it is necessary to reduce the capacitance C to about 8 nF, as illustrated in FIG. 6B. Reducing the capacitance C from 20 nF to 8 nF also has physical restrictions, and it is thus very difficult to realize it. Thus, for reducing the resistance R and the capacitance C of the counter electrode 12 or the shield electrode 17, there are physical restrictions in increasing the width of a voltage supply circuit to the counter electrode 12 or the shield electrode 17, reducing the resistance value due to multilayered wiring, and reducing a capacitance due to change of material.

The results illustrated in FIGS. 6A and 6B mean that the effects of a low-pass filter increase as the resistance R and the capacitance C increase. That is, although low-frequency components can pass through the low-pass filter, high-frequency components decay significantly. The amount of decay of the high-frequency components increases, as the resistance R and the capacitance C increase.

For example, the resistance R increases, as the distance from the voltage supply circuit 32 to the counter electrode 12 and the distance from the voltage supply circuit 35 to the shield electrode 17 increase physically. Thus, when the voltage supply circuit 32 and the voltage supply circuit 35 are arranged outside the pixel region, the high-frequency components are likely to decay more significantly in the pixels 10 in the vicinity of a center portion of the pixel region than in an outer peripheral portion of the pixel region. Thus, since the amount of decay of the high-frequency components in the outer peripheral portion of the pixel region and the amount of decay of the high-frequency components in the center portion differ from each other, it is difficult to acquire an image in which the sensitivity is uniform in the entire pixel region.

For reducing the response time in the default settings to half by only changing the power supply E, it is necessary to increase the power supply E by about 4 V, as illustrated in FIG. 6C. A change that increases the power supply E from 10 V to 14 V can be realized as long as the reliability of a transistor related to the voltage application can be satisfied. Thus, increasing the power supply E is effective in reducing the response time. Also, increasing the power supply E can suppress the decay of the high-frequency components which is caused by low-pass filter characteristics and can obtain the high-frequency components in the pixel-region center portion where the resistance R is high, and the high-frequency components are likely to decay significantly. Thus, increasing the power supply E is effective in sensitivity ununiformity in the pixel region.

Accordingly, in order to reduce the response time and to suppress the sensitivity ununiformity in the pixel region, the imaging device 100 according to the present embodiment more greatly changes the voltage supplied by the voltage supply circuit 32 or the voltage supply circuit 35 than a voltage to be applied to the counter electrode 12 or the shield electrode 17. Also, since the reliability of a transistor is determined by a product of the voltage value and the time of a voltage that is applied, the period in which the voltage supplied by the voltage supply circuit 32 or the voltage supply circuit 35 changes greatly is reduced in the imaging device 100. An operation example of the imaging device 100 according to the present embodiment will be described in detail.

### (1) Operation Example 1

First, a description will be given of operation example 1 of the imaging device 100 according to the present embodiment. In operation example 1, the voltage supply circuit 32 supplies three different types of voltage to the counter electrode 12.

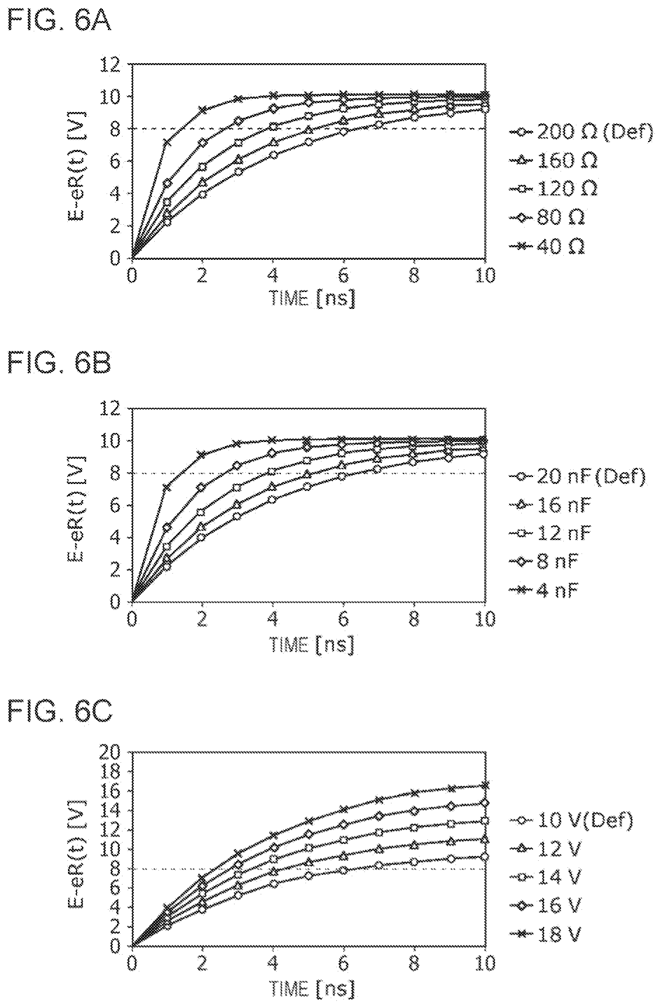

FIG. 7 is a graph illustrating a relationship between the voltage at the counter electrode 12 and the pixel signal reading in operation example 1 of the imaging device 100 according to the present embodiment. The dashed curve line in “Vb” in FIG. 7 represents the voltage Vreal in the example illustrated in FIG. 3B.

In operation example 1, it is assumed that, as in a voltage Vset illustrated in FIG. 7, the voltage supply circuit 32 attempts to change the voltage Vb at the counter electrode 12 to three-value pulsed voltages, that is, a low-level voltage VL, a high-level voltage VH, and a voltage VHH, which is higher than the voltage VH. Specifically, the voltage supply circuit 32 alternately supplies the voltage VL and the voltage VH, which is different from the voltage VL. The voltage supply circuit 32 also supplies the voltage VHH to the counter electrode 12 in a period T3 between a period T1 in which the voltage VL is supplied and a period T2 that is subsequent to the period T1 and in which the voltage VH is supplied. The voltage VH is a voltage between the voltage VL and the voltage VHH. The “period T2 that is subsequent to the period T1 and in which the voltage VH is supplied” is a certain period after the period T1 in which the voltage supply circuit 32 supplies the voltage VL, for example, a certain period in which the voltage VH is supplied and that is included in a period after the period T1 in which the voltage supply circuit 32 supplies the voltage VL until the voltage supply circuit 32 supplies the voltage VL again after changing the voltage that is supplied. Also, the period T1 is one example of a first period, and the period T2 is one example of a second period.

When the voltage supply circuit 32 supplies the three-value pulsed voltage Vset illustrated in FIG. 7, the voltage VHH is supplied even when there is a delay due to the RC time constant. Thus, compared with the case of the two-value pulsed voltage Vset described in the above examples, it is possible to accelerate the rising of the voltage Vreal in practice. That is, it is possible to sharply change the voltage Vreal. In operation example 1, the voltage Vreal can be increased to a level that is sufficiently close to the voltage Vset, and the voltage Vreal reaches the voltage VH in the high sensitivity exposure period without extending the high sensitivity exposure period, as in the example illustrated in FIG. 4. Hence, since the sensitivity of the photoelectric converting portion 13 can be sufficiently increased, it is possible to acquire a favorable image with sufficient sensitivity.

Also, the period T3 in which the voltage supply circuit 32 supplies the voltage VHH and the period T2 in which the voltage supply circuit 32 supplies the voltage VH exist in the high sensitivity exposure period. That is, since the voltage supply circuit 32 supplies the voltage VHH in only a certain period in the high sensitivity exposure period, the reliability of a transistor related to the circuit for supplying the voltage is more likely to be kept. Thus, it is possible to suppress changes in the performance of transistors used for realizing the imaging device 100. From the perspective of the reliability of the transistor, the period T3 may be shorter than the period T2.

As illustrated in FIG. 7, the period T1 may be longer than the period T2. Also, the period T1 may be longer than a total period of the period T2 and the period T3. That is, the period T2 and the total period of the period T2 and the period T3 may be shorter than the period T1. Even when the period T2 and the total period of the period T2 and the period T3 are short, the voltage supply circuit 32 supplies the voltage VHH in the period T3, thus accelerating the voltage change in the voltage Vreal. This facilitates that the voltage at the counter electrode 12 reaches a voltage needed for intended sensitivity adjustment.

As described above, in this operation example, when the voltage Vb at the counter electrode 12 transitions from the low level to the high level, the voltage Vset supplied by the voltage supply circuit 32 is a three-value pulsed voltage. That is, the voltage VHH is supplied to the counter electrode 12 in the period T3 between the period T1 in which the voltage supply circuit 32 supplies the voltage VL and the period T2 that is subsequent to the period T1 and in which the voltage supply circuit 32 supplies the voltage VH. This allows the actual voltage Vreal at the counter electrode 12 to increase to the high-level voltage VH, in the high sensitivity exposure period without extending the high sensitivity exposure period. Thus, it is possible to acquire a favorable image in the high sensitivity exposure period. Hence, it is possible to realize the imaging device 100 that allows the sensitivity adjustment while ensuring the frame rate.

### (2) Operation Example 2

Next, a description will be given of operation example 2 of the imaging device 100 according to the present embodiment. In operation example 2, the voltage supply circuit 32 supplies four different types of voltage to the counter electrode 12.

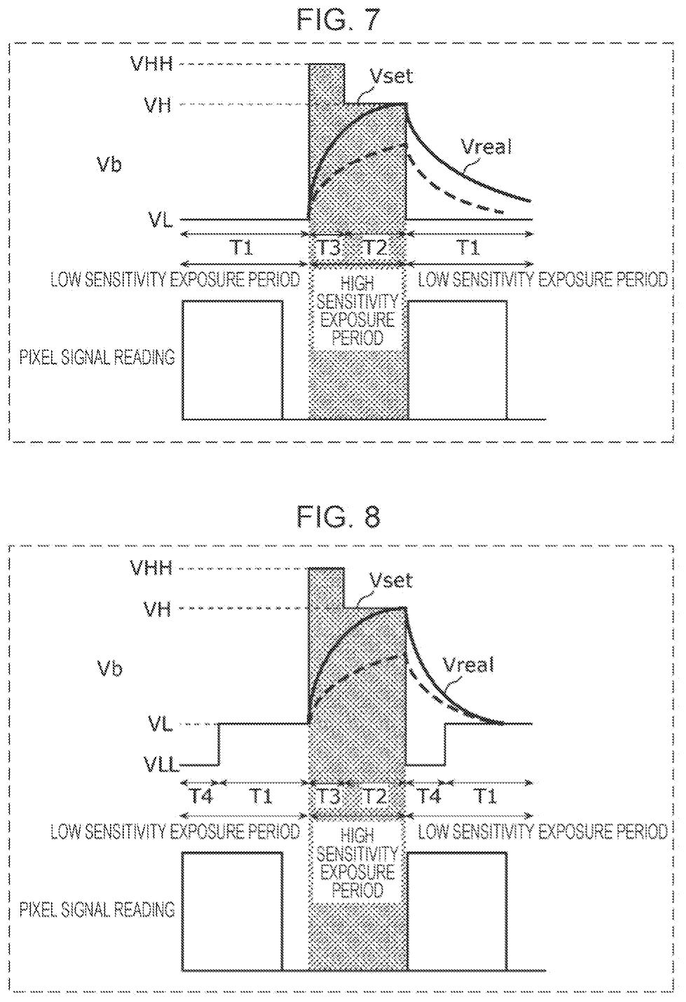

FIG. 8 is a graph illustrating a relationship between the voltage at the counter electrode 12 and the pixel signal reading in operation example 2 of the imaging device 100 according to the present embodiment. The dashed curve line in “Vb” in FIG. 8 represents the voltage Vreal in the example illustrated in FIG. 3B.

In operation example 2, it is assumed that, as in a voltage Vset illustrated in FIG. 8, the voltage supply circuit 32 attempts to change the voltage Vb at the counter electrode 12 to four-value pulsed voltages, that is, a low-level voltage VL, a high-level voltage VH, a voltage VHH, which is higher than the voltage VH, and a voltage VLL, which is lower than the voltage VL. Specifically, in addition to supplying the voltage VL, the voltage VH, and the voltage VHH in operation example 1, the voltage supply circuit 32 supplies the voltage VLL to the counter electrode 12 in a period T4 between a period T2 in which the voltage VH is supplied and a period T1 that is subsequent to the period T2 and in which the voltage VL is supplied. The voltage VL is a voltage between the voltage VH and the voltage VLL. The “period T1 that is subsequent to the period T2 and in which the voltage VL is supplied” is a certain period after the period T2 in which the voltage supply circuit 32 supplies the voltage VH, for example, a certain period in which the voltage VL is supplied and that is included in a period after the period T2 in which the voltage supply circuit 32 supplies the voltage VH until the voltage supply circuit 32 supplies the voltage VH again after changing the voltage that is supplied.

When the voltage supply circuit 32 supplies the four-value pulsed voltage Vset illustrated in FIG. 8, the voltage VHH and the voltage VLL are supplied even when there is a delay due to the RC time constant. Thus, the rising and the falling of the virtual voltage Vreal can be accelerated compared with the case of the two-value pulsed voltage Vset described in the above examples. That is, it is possible to sharply change the voltage Vreal. In operation example 2, the voltage Vreal can be increased to a level that is sufficiently close to the voltage Vset, and the voltage Vreal reaches the voltage VH in the high sensitivity exposure period. Hence, the sensitivity of the photoelectric converting portion 13 is sufficiently increased, thus making it possible to acquire a favorable image.

In the low sensitivity exposure period, the voltage Vreal also reaches the voltage VL. Thus, the resetting and reading can be performed in a state in which the potential of the counter electrode 12 is stable, thus making it possible to acquire a favorable image.

Also, the period T4 in which the voltage supply circuit 32 supplies the voltage VLL and the period T1 in which the voltage supply circuit 32 supplies the voltage VL exist in the low sensitivity exposure period. Since the voltage supply circuit 32 supplies the voltage VLL in only a certain period in the low sensitivity exposure period, the reliability of a transistor related to the circuit for supplying the voltage is more likely to be maintained. Thus, it is possible to suppress changes in the performance of transistors used for realizing the imaging device 100. From the perspective of the reliability of the transistors, the period T4 may be shorter than the period T1.

As described above, in this operation example, the voltage Vset supplied by the voltage supply circuit 32 is a four-value pulsed voltage. That is, in addition to the operation in operation example 1, the voltage supply circuit 32 supplies the voltage VLL to the counter electrode 12 in the period T4 between the period T2 in which the voltage supply circuit 32 supplies the voltage VH and the period T1 that is subsequent to the period T2 and in which the voltage supply circuit 32 supplies the voltage VL. This makes it possible to not only increase the virtual voltage Vreal at the counter electrode 12 to the high-level voltage VH in the high sensitivity exposure period without extending the high sensitivity exposure period but also reduce the virtual voltage Vreal at the counter electrode 12 to the low-level voltage VL in the low sensitivity exposure period without extending the low sensitivity exposure period. As a result, a favorable image can be acquired. Hence, it is possible to realize the imaging device 100 that allows the sensitivity adjustment while ensuring the frame rate.

Although an example in which the voltage supply circuit 32 supplies a three-value pulsed or four-value pulsed voltage has been described in operation examples 1 and 2, the pulse may have five or more values in order to further reduce the response time.

Although an example in which the voltage Vb is set to the high level in the high sensitivity exposure period to increase the sensitivity, and the voltage Vb is set to the low level in the low sensitivity exposure period to reduce the sensitivity has been described in operation examples 1 and 2, the present disclosure is not limited thereto. The voltage Vb may be set to the low level in the high sensitivity exposure period to increase the sensitivity, and the voltage Vb may be set to the high level in the low sensitivity exposure period to reduce the sensitivity. Such sensitivity adjustment is performed, for example, when electrons are used as the signal charge, and the reset voltage Vr has a value that is closer to the high-level voltage VH than to the low-level voltage VL. Specifically, during change of the voltage Vb from the low sensitivity exposure period to the high sensitivity exposure period, that is, in a period between the period in which the voltage supply circuit 32 supplies the voltage VH and the subsequent period in which the voltage supply circuit 32 supplies the voltage VL, the voltage VLL, which is lower than the voltage VL, is supplied to the counter electrode 12. Also, during change of the voltage Vb from the high sensitivity exposure period to the low sensitivity exposure period, that is, in a period between the period in which the voltage supply circuit 32 supplies the voltage VL and the subsequent period in which the voltage supply circuit 32 supplies the voltage VH, the voltage VHH, which is higher than the voltage VH, is supplied to the counter electrode 12. This makes it possible to reduce the response time delay due to the RC time constant.

In operation examples 1 and 2, although the operation is started from the low sensitivity exposure period, the operation may be started from the high sensitivity exposure period.

### (3) Other Operation Examples

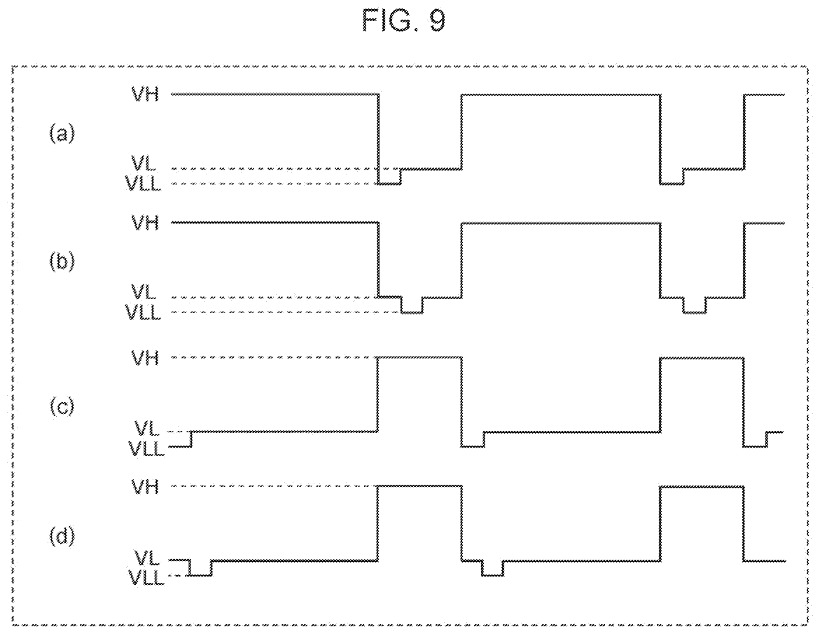

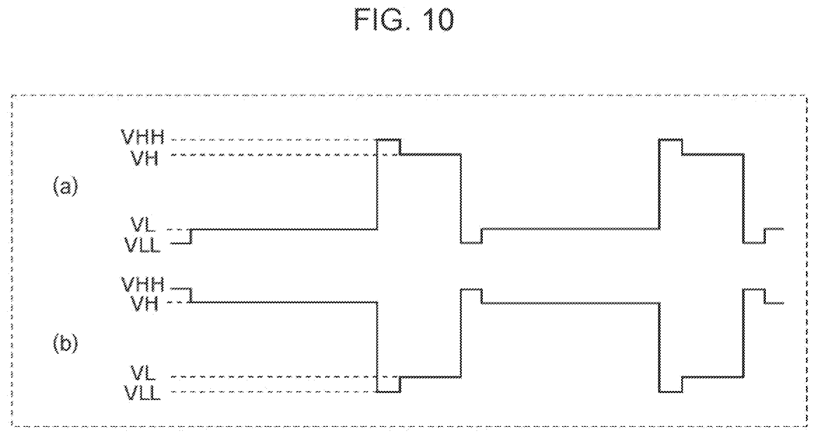

Next, a description will be given of other operation examples of the imaging device 100 according to the present embodiment. FIGS. 9 and 10 illustrate voltages supplied by the voltage supply circuit 32 in other operation examples of the imaging device 100 according to the present embodiment. FIGS. 9(a) to 9(d) and FIGS. 10(a) and 10(b) are graphs each illustrating changes over time in the voltage supplied by the voltage supply circuit 32. That is, FIGS. 9(a) to 9(d) and FIGS. 10(a) and 10(b) each illustrate the voltage Vset described above. In FIGS. 9(a) to 9(d) and FIGS. 10(a) and 10(b), the voltage supply circuit 32 alternately supplies the voltage VL and the voltage VH, as in the above-described operation examples.

For example, when the voltage supply circuit 32 supplies the three-value pulsed voltage, the voltage supply circuit 32 may supply the voltage VLL in a period between the period in which the voltage VH is supplied and a period in which the voltage VL is supplied, as illustrated in FIG. 9(a). The voltage VL is a voltage between the voltage VH and the voltage VLL.

Also, the period immediately after the period in which the voltage supply circuit 32 supplies the voltage VH does not necessarily have to be the period in which the voltage VLL is supplied, as illustrated in FIG. 9(a), and a period in which a voltage that is different from the voltage VH and the voltage VLL is supplied may be provided between the period in which the voltage VH is supplied and the period in which the voltage VLL is supplied. That is, the period in which the voltage supply circuit 32 supplies the voltage VLL, the period being provided between the period in which the voltage supply circuit 32 supplies the voltage VH and the subsequent period in which the voltage VL is supplied, does not necessarily have to be immediately after the period in which the voltage VH is supplied. For example, the period in which the voltage VL is supplied may be provided between the period in which the voltage supply circuit 32 supplies the voltage VH and the period in which the voltage supply circuit 32 supplies the voltage VLL, as illustrated in FIG. 9(b).

Also, for example, the period in which the voltage supply circuit 32 supplies the voltage VL may be shorter than the period in which the voltage supply circuit 32 supplies the voltage VH, as illustrated in FIG. 9(a). In addition, the period in which the voltage supply circuit 32 supplies the voltage VL may be longer than the period in which the voltage supply circuit 32 supplies the voltage VH, as illustrated in FIG. 9(c).

In addition, for example, even when the period in which the voltage supply circuit 32 supplies the voltage VL is longer than the period in which the voltage supply circuit 32 supplies the voltage VH, a period in which the voltage VL is supplied may be provided between the period in which the voltage supply circuit 32 supplies the voltage VH and the period in which the voltage supply circuit 32 supplies the voltage VLL, as illustrated in FIG. 9(d).

Also, for example, when the voltage supply circuit 32 supplies the four-value pulsed voltage, the period in which the voltage supply circuit 32 supplies the voltage VL may be longer than the period in which the voltage supply circuit 32 supplies the voltage VH, as illustrated in FIG. 10(a). The period in which the voltage supply circuit 32 supplies the voltage VL may be shorter than the period in which the voltage supply circuit 32 supplies the voltage VH, as illustrated in FIG. 10(b).

In FIGS. 9 and 10, the period in which the voltage supply circuit 32 supplies the voltage VH and the voltage VHH and the period in which the voltage supply circuit 32 supplies the voltage VL and the voltage VLL may be the high sensitivity exposure period and the low sensitivity exposure period, respectively, or may be the other way around. In addition, the signal reading of the pixel 10 may be performed in the low sensitivity exposure period or may be performed in the high sensitivity exposure period.

Herein, one of a pair of the voltage VH and the voltage VHH and a pair of the voltage VL and the voltage VLL is one example of a first voltage and a fourth voltage, and the other pair is one example of a second voltage and a third voltage.

Although an example in which the sensitivity of the photoelectric converting portion 13 can be adjusted by changes in the voltage applied to the counter electrode 12 has been described above in each operation example of the imaging device 100 according to the present embodiment, the sensitivity of the photoelectric converting portion 13 can also be adjusted by changes in the voltage applied to the shield electrode 17, as described above. When the voltage supply circuit 35 supplies the voltage to the shield electrode 17, the voltage supply circuit 35 may execute an operation that is the same as or similar to the operation of the voltage supply circuit 32 in each operation example of the imaging device 100 according to the present embodiment, and such an operation makes it possible to realize the imaging device 100 that allows sensitivity adjustment while ensuring the frame rate. In such an aspect, the shield electrode 17 is one example of the second electrode.

### Second Embodiment

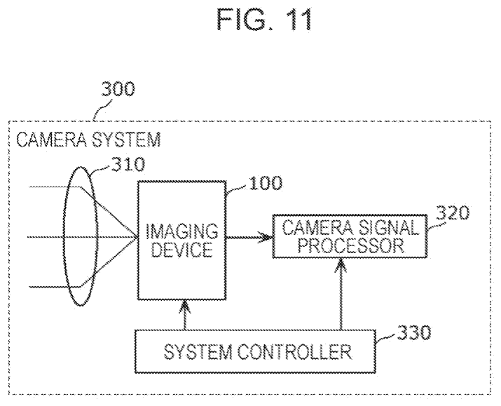

Next, a second embodiment will be described. In the present embodiment, a description will be given of a camera system using the imaging device according to the above-described embodiment. FIG. 11 is a block diagram illustrating one example of the configuration of a camera system 300 according to the present embodiment.

The camera system 300 according to the present embodiment is used for, for example, a smartphone, a video camera, a digital still camera, a surveillance camera, or a vehicle-mounted camera. The camera system 300 includes the imaging device 100, a lens 310, a camera signal processor 320, and a system controller 330. The lens 310 is an optical element for guiding incident light to an imaging plane, which is a part of the pixel region in the imaging device 100. The imaging device 100 converts light of an image, formed in the imaging plane by the lens 310, into electrical signals for the respective pixels 10 and outputs resulting image signals.

The camera signal processor 320 performs various types of processing on the image signals generated by the imaging device 100. The camera signal processor 320 performs processing, for example, gamma correction, color interpolation processing, spatial interpolation processing, automatic white balance, distance measurement arithmetic operation, and wavelength information separation. The camera signal processor 320 can be implemented by, for example, a digital signal processor (DSP).

The system controller 330 is a control unit that controls driving of the imaging device 100 and the camera signal processor 320. The system controller 330 can be implemented by, for example, a microcomputer. The image signals processed by the camera signal processor 320 are recorded to, for example, a recording medium, such as a memory, as a still image or a moving image. Alternatively, the image signals are shown on a monitor, such as a liquid-crystal display, as a moving image. By using the imaging device 100 according to the above-described embodiment, the camera system 300 according to the present embodiment allows sensitivity adjustment while ensuring the frame rate.

### OTHER EMBODIMENTS

Although the imaging device and the camera system according to one or more aspects have been described above based on the embodiments, the present disclosure is not limited to the embodiments.

Also, although the signal reading is performed in the low sensitivity exposure period in operation examples 1 and 2 in the above embodiments, the present disclosure is not limited thereto. The signal reading may also be performed in the high sensitivity exposure period.

In addition, although the photoelectric conversion layer 15 is constituted by a single layer in the embodiments described above, the photoelectric conversion layer 15 may be constituted by a plurality of layers. For example, the photoelectric conversion layer 15 may be a composite layer including at least one of a p-type semiconductor layer and an n-type semiconductor layer.

In addition, modes obtained by making various modifications conceived by those skilled in the art to the embodiments and modes constructed by combining some of the constituent elements in different embodiments are also encompassed by the scope of the present disclosure, as long as such modes do not depart from the spirit of the present disclosure.

The imaging device according to the present disclosure can be used for various sensor systems and camera systems, such as digital still cameras, medical cameras, surveillance cameras, vehicle-mounted cameras, digital single-lens reflex cameras, and digital mirrorless single-lens reflex cameras.

What is claimed is:

1. An imaging device comprising:
a first electrode;
a second electrode;
a photoelectric conversion layer that is located between the first electrode and the second electrode and that generates signal charge;
a charge accumulation portion that is connected to the first electrode to accumulate the signal charge; and
a voltage supply circuit that alternately supplies a first voltage and a second voltage different from the first voltage to the second electrode,
wherein the voltage supply circuit supplies a third voltage to the second electrode in a period between a first period in which the first voltage is supplied and a second period that is subsequent to the first period and in which the second voltage is supplied; and
the second voltage is a voltage between the first voltage and the third voltage.

2. The imaging device according to claim 1,
wherein a length of the first period is greater than a length of the second period.

3. The imaging device according to claim 1,
wherein the voltage supply circuit supplies a fourth voltage to the second electrode in a period between the second period and the first period that is subsequent to the second period, and
the first voltage is a voltage between the second voltage and the fourth voltage.

4. The imaging device according to claim 1,
wherein the photoelectric conversion layer has a first surface and a second surface that is opposite the first surface; and
the first electrode faces the first surface of the photoelectric conversion layer, and the second electrode faces the second surface of the photoelectric conversion layer.

5. The imaging device according to claim 1,
wherein the photoelectric conversion layer has a first surface and a second surface that is opposite the first surface; and
the first electrode and the second electrode face the first surface of the photoelectric conversion layer.
